(19) United States
(12) Patent Application Publication
(10) Pub. No.: US 2021/0082456 A1
(43) Pub. Date: Mar. 18, 2021

(54) SPEECH PROCESSING APPARATUS AND TRANSLATION APPARATUS

(71) Applicant: Panasonic Intellectual Property Management Co., Ltd., Osaka (JP)

(72) Inventor: Tomokazu ISHIKAWA, Osaka (JP)

(21) Appl. No.: 17/105,894

(22) Filed: Nov. 27, 2020

Related U.S. Application Data
(63) Continuation of application No. PCT/JP2018/044735, filed on Dec. 5, 2018.

(30) Foreign Application Priority Data
Jun. 8, 2018 (JP) 2018-110621

(51) Int. Cl. G10L 25/78; G06F 40/42; G06F 3/16; G06F 9/54

(52) U.S. Cl. CPC G10L 25/78; G06F 40/42; G10L 2025/783; G06F 9/542; G06F 3/16

(57) ABSTRACT

A speech processing apparatus includes an input device, a control circuit, and an output device. The input device receives speech to generate an input speech signal. The control circuit performs a signal generation process, a level detection process, and an output speech conversion process. The signal generation process generates a first output speech signal based on the input speech signal. The level detection process detects a first period at which a signal level of the input speech signal is greater than a predetermined value. The output speech conversion process performs signal processing to generate a second output speech signal. The signal processing is performed to the first output speech signal during a second period that corresponds to the first period, and is different from another signal processing performed during another period. The output device outputs speech based on the second output speech signal.

### CROSS REFERENCE TO RELATED APPLICATION(S)

This is a continuation application of International Application No. PCT/JP2018/044735, with an international filing date of Dec. 5, 2018, which claims priority of Japanese Patent Application No. 2018-110621 filed on Jun. 8, 2018, each of the content of which is incorporated herein by reference.

### BACKGROUND

### 1. Technical Field

The present disclosure provides a speech processing apparatus that can help a speaker(s) to be aware of inputting the speech at an excessive volume.

### 2. Related Art

Japanese Laid-Open Patent Publication No. 2014-21485 discloses a television system which is capable of translating input speech in one language into speech in multiple languages. The television system decomposes an input speech signal with respect to volume, tone, and timbre. The television system outputs translated speech signals in multiple language in which the decomposed volume, tone, and timbre are fused.

### SUMMARY

A Speech processing apparatus is provided, which can help a speaker(s) to be aware that he or she is inputting their speech at an excessive volume.

A speech processing apparatus includes an input device, a control circuit, and an output device. The input device receives speech to generate an input speech signal. The control circuit performs a signal generation process, a level detection process, and an output speech conversion process. The signal generation process generates a first output speech signal based on the input speech signal. The level detection process detects a first period at which a signal level of the input speech signal is greater than a predetermined value. The output speech conversion process performs signal processing to generate a second output speech signal. The signal processing is performed to the first output speech signal during a second period that corresponds to the first period, and is different from another signal processing performed during another period. The output device outputs speech based on the second output speech signal.

According to the present disclosure, it is possible to provide a speech processing apparatus that can help a speaker(s) to be aware that he or she is inputting their speech at an excessive volume.

### BRIEF DESCRIPTION OF DRAWINGS

FIG. 1 shows an external view of a translation apparatus of an exemplary embodiment.

FIG. 2 is a block diagram illustrating a configuration of a translation system of an exemplary embodiment.

FIG. 3A shows a waveform of a speech signal indicated by input speech data with a proper level input to the translation apparatus.

FIG. 3B shows a waveform of a speech signal indicated by input speech data with an excess level input to the translation apparatus.

FIG. 4 is a flowchart illustrating translation process executed by the translation apparatus according to Embodiment 1.

FIG. 5A shows a waveform of a speech signal indicated by the input speech data input to the translation apparatus according to Embodiment 1.

FIG. 5B shows a waveform of a speech signal indicated by the speech synthesis data generated from the input speech data by the translation apparatus according to Embodiment 1.

FIG. 5C shows a waveform of the speech signal indicated by output speech data generated from the speech synthesis data by the translation apparatus according to Embodiment 1.

FIG. 6 is a flowchart illustrating process of generating the output speech data from the speech synthesis data executed by the translation apparatus according to Embodiment 1.

FIG. 7 is a diagram illustrating process of amplifying an output level of the speech synthesis data.

FIG. 8A shows a waveform of a speech signal indicated by the input speech data input to the translation apparatus according to Embodiment 2.

FIG. 8B shows a waveform of a speech signal indicated by the speech synthesis data generated from the input speech data in the translation apparatus according to Embodiment 2.

FIG. 8C shows a waveform of the speech signal indicated by the output speech data generated from the speech synthesis data in the translation apparatus according to Embodiment 2.

FIG. 9 is a flowchart illustrating process of generating the output speech data from the speech synthesis data executed by the translation apparatus according to Embodiment 2.

FIG. 10 is a block diagram illustrating a configuration of the translation system according to Embodiment 3.

FIG. 11 is a flowchart illustrating operations of a translation apparatus according to Embodiment 3.

FIG. 12 illustrates a scene where an alert message is shown in a display in a translation apparatus according to Embodiment 4.

FIG. 13 is a flowchart illustrating operations of the translation apparatus according to Embodiment 4.

### DETAILED DESCRIPTION

The embodiments will be described in detail with reference to the drawings as appropriate. However, more detailed explanations than are necessary may be omitted. For example, in some cases, detailed explanations of already well-known matters and duplicate explanations for substantially identical configurations are omitted. This is to avoid unnecessary redundancy in the description below and to facilitate the understanding of those skilled in the art.

The inventor(s) have provided the accompanying drawings and the following description in order for those skilled in the art to fully understand the present disclosure. They should not be interpreted as limiting the subject matter described in the claims. In each of the following embodiments, a translation apparatus will be described as an embodiment(s) of a speech processing apparatus.

### Embodiment 1

### 1. Configuration

### 1-1. Outline of Translation Apparatus

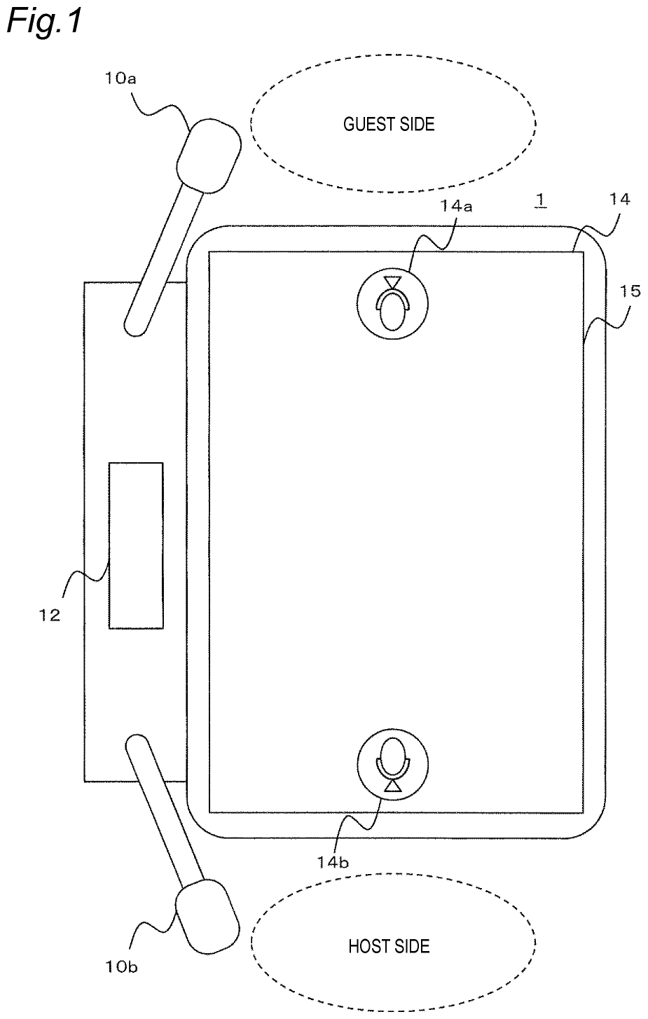

FIG. 1 shows an external view of a translation apparatus, which is an embodiment of a speech processing apparatus according to Embodiment 1. The translation apparatus 1 shown in FIG. 1 translates a conversation between a host speaking in the first language and a guest speaking in the second language. Through the translation apparatus 1, a host and a guest can talk face-to-face in their respective languages. The translation apparatus 1 performs translation from a first language to a second language and also performs translation from a second language to a first language. The translation apparatus 1 outputs translation results as speech spoken aloud. The host and the guest can understand each other what the other person speaks through the speech output from the translation apparatus 1. The first language is Japanese and the second language is English, for example.

The translation apparatus 1 includes a guest-side microphone 10a, a host-side microphone 10b, a speaker 12, a display 14, and a touchscreen panel 15. The guest side microphone 10a and the host side microphone 10b are examples of an input device. The speaker 12 is an example of an output device.

The guest-side microphone 10a receives and converts speech uttered by the guest into input speech data as a digital speech signal. The host-side microphone 10b receives and converts speech uttered by the host into input speech data as a digital speech signal. That is, the guest side microphone 10a and the host side microphone 10b respectively function as speech input devices to the input speech data into the speech processing unit 1.

The display 14 displays texts and/or images based on operations by the guest or host. The display 14 includes a liquid crystal display or an OLED display or the like. The display 14 is an example of an output device.

The touchscreen panel 15 is disposed superimposed on the display 14. The touchscreen panel 15 can accept touch operations by the guest or host.

The speaker 12 is a device to output speech, e.g., to output speech indicating content of the translation results.

In FIG. 1, the translation apparatus 1 displays on a display 14 a speech input button 14a on the guest side and a speech input button 14b on the host side. The translation apparatus 1 respectively detects inputs to the speech input buttons 14a and 14b through inputs to the touchscreen panel 15.

Upon detection of the input to the speech input button 14a by the guest, the translation apparatus 1 starts acquiring the input speech data from the guest-side microphone 10a. When the translation apparatus 1 again detects the input to the speech input button 14a, the apparatus 1 stops acquisition of the input speech data. The translation apparatus 1, for example, performs translation process from English to Japanese and outputs output speech data from the speaker 12 as speech in Japanese.

Similarly, upon detection of the input to the speech input button 14b by the host, the translation apparatus 1 starts acquiring the input speech data from the host-side microphone 10b. When the translation apparatus 1 again detects the input to the speech input button 14b, the apparatus 1 stops acquisition of the input speech data. The translation apparatus 1, for example, performs translation process from Japanese to English and outputs the output speech data from the speaker 12 as speech in English. Note that, by detecting respective volume levels of the input speech data from the guest-side microphone 10a and the host-side microphone 10b to be fallen below a predetermined threshold level, the apparatus 1 may stop acquisition of the input speech data automatically.

### 1-2. Configuration of Translation System

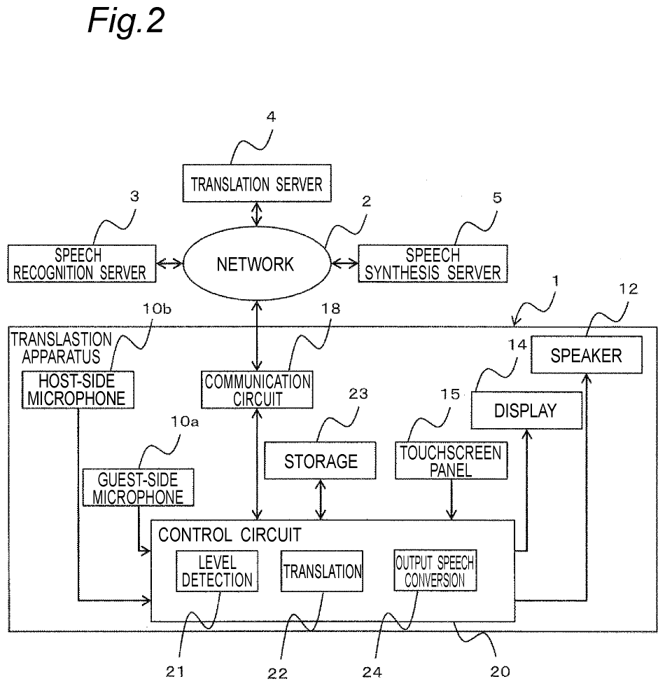

FIG. 2 is a block diagram illustrating a configuration of a translation system according to the present embodiment. In addition to the translation apparatus 1 of FIG. 1, the translation system shown in FIG. 2 further includes, a speech recognition server 3, a translation server 4, and a speech synthesis server 5.

The speech recognition server 3 is a server that receives the input speech data from the translation apparatus 1 via the network 2 and recognize speech from the input speech data to generate speech recognition data of a character string.

The translation server 4 is a server that receives speech recognition data from the translation apparatus 1 via the network 2 and translates the speech recognition data to generate translation data of a character string. In this embodiment, the translation server 4 translates a string of Japanese characters into that of English characters or a string of English characters into that of Japanese characters.

The speech synthesis server 5 is a server that receives translation data of character strings from the translation apparatus 1 via the network 2 and performs speech synthesis processing of the translation data to generate speech synthesis data.

### 1-3 Internal Configuration of Translation Apparatus

The translation apparatus 1 further includes a storage 23, a communication unit 18, and a control circuit 20.

The storage 23 includes a non-transitory computer-readable storage medium, such as a flash memory, an SSD (Solid State Drive), optical disc and/or a hard disk or the like. The storage 23 stores one or more computer programs and data necessary to perform various functions of the translation apparatus 1.

The control circuit 20 includes a CPU or MPU, etc., that, for example, collaborates with software to perform a predetermined function(s). The control circuit 20 controls overall operations of the translation apparatus 1. The control circuit 20 reads out the predetermined programs, data and the like stored in the storage 23 and performs arithmetic processing to realize various functions. For example, the control circuit 20 performs, as its function, a level detection process 21, a translation process 22, and an output speech conversion process 24. The control circuit 20 may be an electronic circuit which is designed exclusively to perform the predetermined function(s). That is, the control circuit 20 may include one or more various types of processors such as a CPU, MPU, GPU, DSP, FPGA, or ASIC. The above respective process 21, 22, and 24 may be performed by separate processors. The translation process 22 is an example of signal generation process performed by the control circuit 20.

In level detection process 21, the control circuit 20 detects whether or not the input level of the input speech data input by the host or guest exceeds a predetermined threshold value.

In the translation process 22, the control circuit 20 carries out translation processes in conjunction with an external speech recognition server 3, translation server 4 and speech synthesis server 5. Specifically, the control circuit 20 generates a speech synthesis data, which is a data for producing speech indicating content of translation results, from speech data input from the microphone 10a/10b with the speech recognition server 3, the translation server 4 and the speech synthesis server 5.

In the output speech conversion process 24, the control circuit 20 converts the speech synthesis data received from speech synthesis server 5 via the network 2 into the output speech data based on the input level detected in the level detection process 21.

The communication unit 18 transmits from the translation apparatus 1 various types of information to an external server(s) and/or receives various types of information from an external server(s), via the network 2 under control of the control circuit 20. The communication unit 18 includes one or more communication modules and/or some types of communication circuits that communicates in accordance with one or more prescribed communication standards such as 3G, 4G, Wi-Fi, Bluetooth (registered trademark), LAN, etc.

### 2) One or More Problems Recognized by the Inventor(s)

In the translation processing system configured as described above, there are some circumstances in which the speech processing system improperly translates input speeches when a guest or host inputs their speech into the translation apparatus 1 at an excessive volume. This will be discussed below.

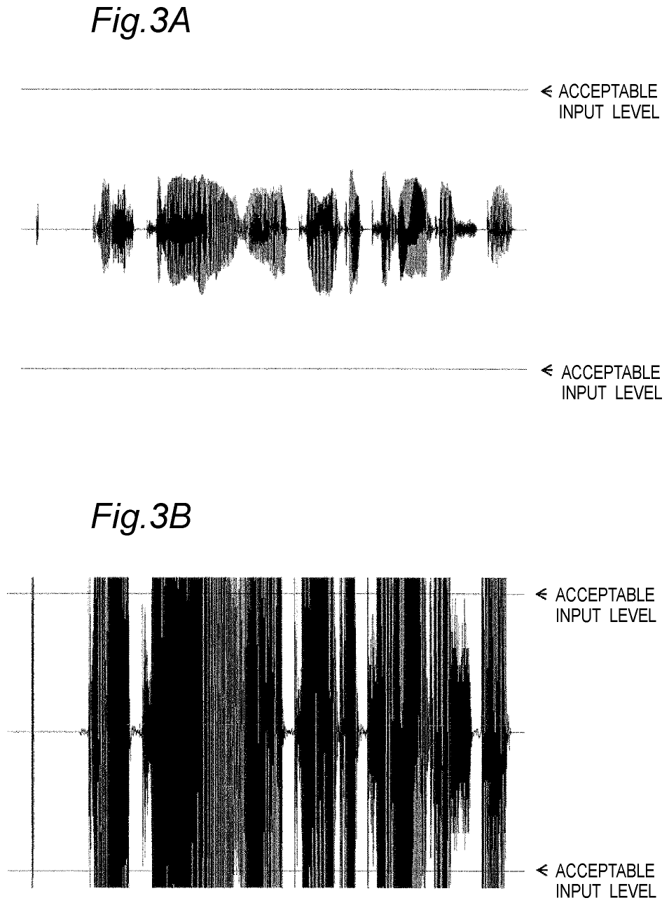

FIGS. 3A and 3B illustrate waveforms of speech signals indicated by the speech data input to the translation apparatus 1. FIG. 3A shows a waveform of a speech signal indicated by the speech data for a speech with a proper input level. The term “proper” means that a speech has a level that is equal to or less than a predetermined acceptable upper input level and that is equal to or more than a predetermined acceptable lower input level, that is, a speech has a level that is within a range between a predetermined acceptable upper and lower input levels. In the speech data of FIG. 3A, the waveform is not saturated and distorted. In this case, the translation processing system can correctly recognize the speech data.

FIG. 3B, on the other hand, shows a waveform of a speech signal indicated by the speech data obtained when a speech is input with an excess input level, that is, an input level has more than the acceptable upper input level and/or less than the acceptable lower input level. In the speech data in FIG. 3B, since the waveform is saturated and distorted, the speech processing system could fail to recognize a proper waveform of the speech signal.

In light of the above, the present disclosure provides a speech processing apparatus that can help guests or hosts to be aware that he or she is inputting their speech data at an excessive volume.

### 3. Operations

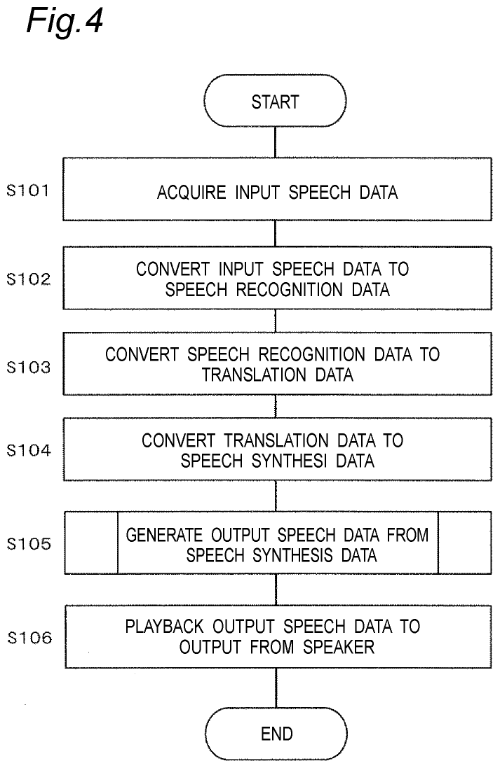

Operations of the translation apparatus 1 will be described with reference to FIGS. 4 to 7. FIG. 4 is a flowchart illustrating translation process by the translation apparatus 1 in the present embodiment. In the following description, FIG. 4 will be used to discuss the translation process by the translation apparatus 1.

Firstly, when the control circuit 20 of the translation apparatus 1 detects pressing of, or inputting to the speech input button 14a or the speech input button 14b, the control circuit 20 acquires the input speech data concerning the speech uttered by the speaker, i.e., the host or the guest, via the host-side microphone 10a or the guest 10b (S101).

Thereafter, the control circuit 20 transmits the input speech data to the speech recognition server 3 via the network 2. The speech recognition server 3 receives the input speech data via the network 2, performs speech recognition process based on the input speech data, and performs conversion into speech recognition data of character strings (S102). The speech recognition data is in text format in the present embodiment. The control circuit 20 of the translation apparatus 1 receives the speech recognition data from the speech recognition server 3 via the network 2 and sends the received speech recognition data to the translation server 4.

The translation server 4 receives the speech recognition data via the network 2, translates the speech recognition data to perform conversion into speech recognition data of character strings (S103). The translation data is in text format. The control circuit 20 of the translation apparatus 1 receives the translation data from the translation server 4 via the network 2 and sends the received translation data to the speech synthesis server 5.

The speech synthesis server 5 receives the translation data via the network 2, performs speech synthesis based on the translation data, and performs conversion into speech synthesis data (S104). The speech synthesis data is data for playback of speech. The control circuit 20 of the translation apparatus 1 the speech synthesis data from speech synthesis server 5 via the network 2.

Thereafter, the control circuit 20 of the translation apparatus 1 generates the output speech data from the speech synthesis data (S105). In particular, when the control circuit 20 determines that the level of the input speech is excessive, the control circuit 20 modulates the speech synthesis data to generate the output speech data in order to present the fact to the speaker(s). Details of the process of generating such an output speech data will be described later.

Finally, the control circuit 20 of the translation apparatus 1 playbacks the output speech data to output a speech indicating the translation results from the speaker 12 (S106).

In the manner as described above, the translation apparatus 1 translates the content of the speech uttered in the first language into the second language and outputs the results of the translation as speech spoken aloud.

Hereinafter, details of the process of generating the output speech data from speech synthesis data (step S105 of FIG. 4) in the translation process described above will be described.

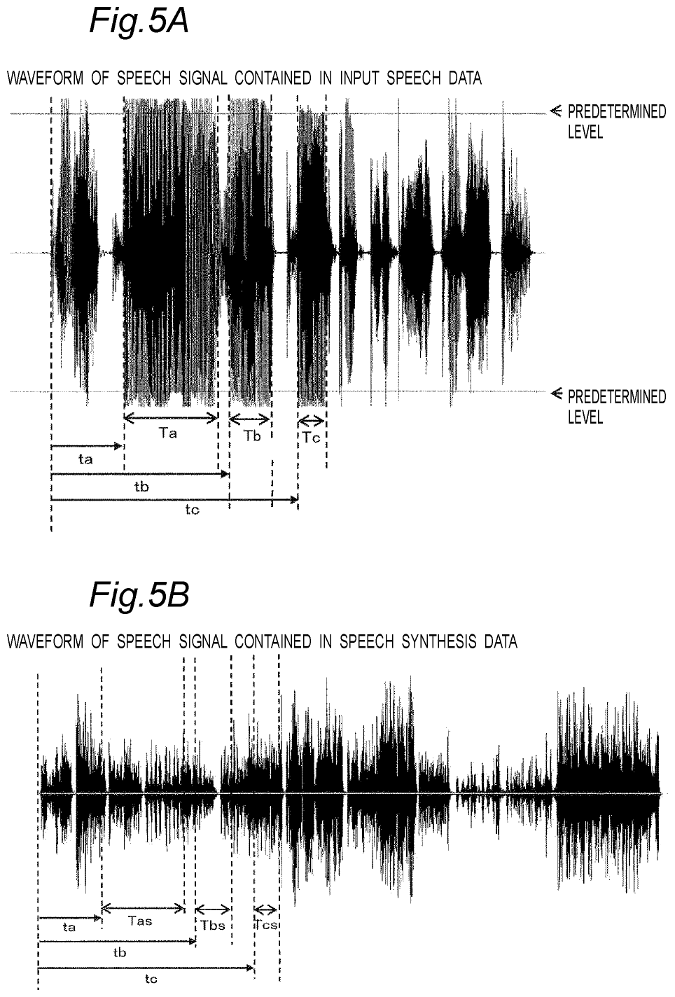

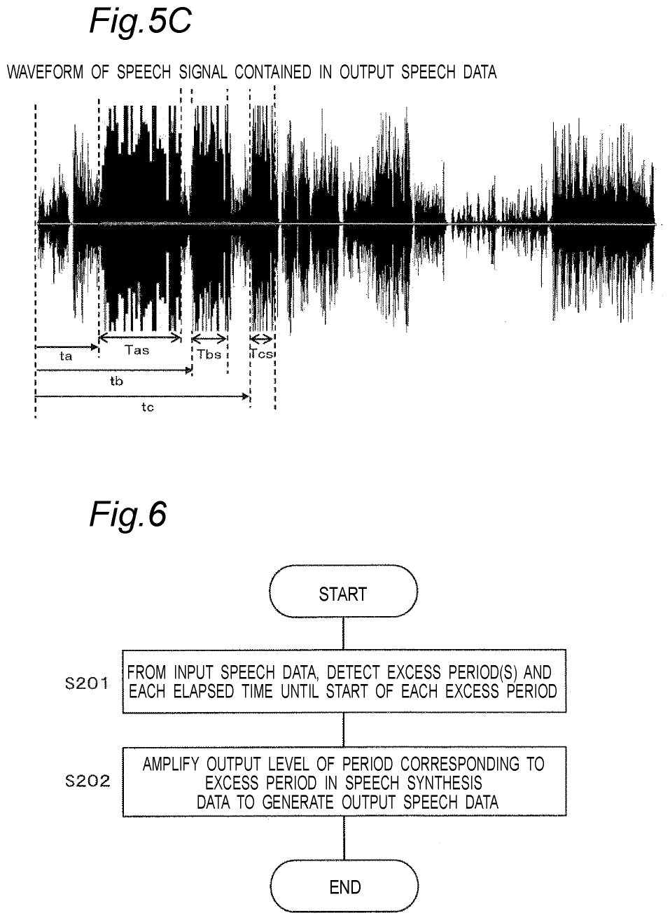

FIGS. 5A, 5B, and 5C are diagrams illustrating speech processing by the translation apparatus 1. FIG. 5A shows a waveform of the speech signal indicated by the input speech data. FIG. 5B shows a waveform of the speech signal indicated by the speech synthesis data converted from the input speech data of FIG. 5A. FIG. 5C shows a waveform of the speech signal indicated by the output speech data converted from the speech synthesis data of FIG. 5B. FIG. 6 is a flowchart illustrating process of generating the output speech data from speech synthesis data in the present embodiment.

In FIG. 6, the control circuit 20 firstly detects in the level detection process 21, an excess period as the first period, and an elapsed time from start of the input speech to the start time of the excess period (S201). The excess period is a period during which the input level of speech indicated by the input speech data exceeds a predetermined upper level. The input level of speech may be an absolute value. In the example of FIG. 5A, the control circuit 20 detects in the level detection process 21, the excess periods Ta, Tb, Tc and the elapsed times ta, tb, tc to the start time of respective excess periods.

Next, in the output speech conversion process 24, the control circuit 20 amplifies an output level of the speech synthesis data within an amplification period as a second period, corresponding to the excess period of the input speech data, to generate the output speech data (S202). In the examples of FIGS. 5B and 5C, the control circuit 20 amplifies, in the output speech conversion process 24, the output speech level of speech synthesis data shown in FIG. 5B, from a point in time at which time to has elapsed from a start point of the speech indicated by the speech synthesis data, through the amplification period Tas. The duration of the amplification period Tas is equal to that of the excess period Ta. Then the control circuit 20 generates the output speech data as shown in FIG. 5C. Similarly, the output speech level of the output speech data shown in FIG. 5C is amplified during amplified periods of Tbs and Tcs. The amplified periods of Tbs and Tcs respectively start from points in time at which times tb and tc from a start point of the speech indicated by the speech synthesis data as shown in FIG. 5B have elapsed, and respectively have durations of the excess periods tb and tc, which are equal to those of the excess periods Tb and Tc.

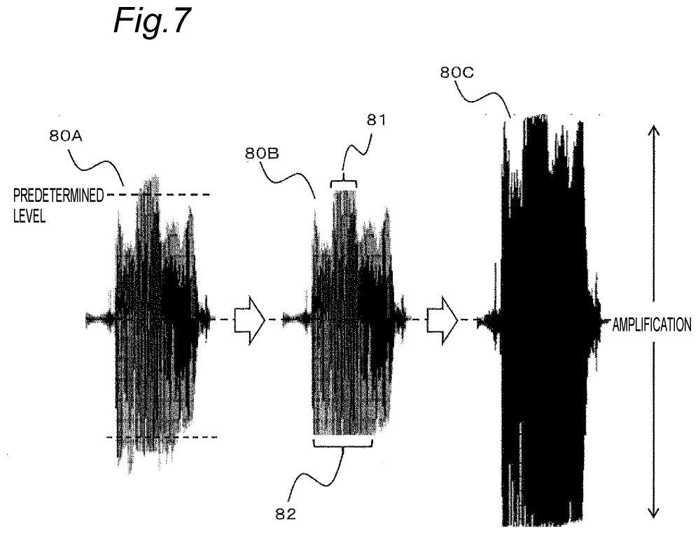

Existing techniques can be used for the amplification process of the output level of the speech synthesis data. For example, the amplification process can be achieved using a known compression processing technique. FIG. 7 is a diagram illustrating known compression processing. As shown in FIG. 7, portions of the speech signal 80A where the signal level exceeds a predetermined level are cut off, and then a speech signal 80B is generated. In the speech signal 80B, portions 81 and 82 of the waveform are cut off. The speech signal 80B with the large amplitude cut-off portions is then amplified to a predetermined amplification level, and amplified speech signal 80C is generated. The speech signal can be amplified in this way.

As described above, the translation apparatus 1 of the present embodiment amplifies a level of an amplification period of the output speech when the input speech has an excess period during which the input speech exceeds a predetermined level. The amplification period corresponds to the excess period. By listening to the speech with some of the levels increased, the speaker of the input speech, i.e., the host or guest, can be aware that the speech uttered by them is excessively loud. Then it can be expected for the speaker of the input speech, i.e., the host or guest, to make the input level adjust to an appropriate input level by moving away from the microphone 10b or 10a, or by turning the volume down.

### 4. Summary

As explained above, the translation apparatus 1 has a guest-side microphone 10a, a host-side microphone 10b, the control circuit 20 executing: a translation process 22; a level detection process 21; and an output speech conversion process 24, and a speaker 12. The guest side microphone 10a and the host side microphone 10b inputs speech indicating content uttered in the first language to generate input speech signals. The control circuit 20 generates in the translation process 22 the first output speech signal which is a speech signal indicating results of translation from an uttered content indicated by the input speech signal to an uttered content in the second language. The control circuit 20 detects in the level detection process 21 an excess period in the input speech signal where the signal level is greater than a predetermined level. The control circuit 20 amplifies, in the output speech conversion process 24, a level of the first output speech signal during a amplification period (the second period) corresponding to an excess period (first period) with an amplification level that is greater than that of the other periods to generate the second output speech signal. The speaker 12 outputs speech based on the second output speech signal.

The duration of the excess period in the input speech signal coincides with the duration of the amplification period in the second output speech signal. The duration from the start time of the input speech signal to the start time of the excess period in the input speech signal coincides with the duration from the start time of the second output speech signal to the start time of the amplification period.

When the input speech has an excess period that exceeds a predetermined level, the translation apparatus 1 of the present embodiment amplifies a level of an amplification period corresponding to the excess period in the output speech. Then it can be expected for the speaker of the input speech, i.e., the host or guest, to make the input level adjust by moving away from the microphone 10b or 10a, or by turning the volume down.

### Embodiment 2

The translation apparatus 1 of Embodiment 1 amplifies a speech level in the output speech data for an amplification period which has the same start timing and the same duration with the excess period of the input speech data. The overall durations of the input speech data and the output speech data are not necessarily the same. For this reason, it may be difficult to know from the output speech which period of the input speech with respect to its overall period had excess input level based on the amplification method of Embodiment 1. In this embodiment, the amplification period is set so that (A) a relative temporal position and a duration ratio of the excessive period to the overall period in the input speech and (B) a relative temporal position and a duration ratio of the amplification period to the overall period of the output speech are equal. Thus, it becomes easier to know from the output speech which part of the input speech has excessive input level with respect to the overall period of the input speech. The process of this embodiment will be described in detail below. A hardware configuration of the translation system according to this embodiment is the same as that of Embodiment 1.

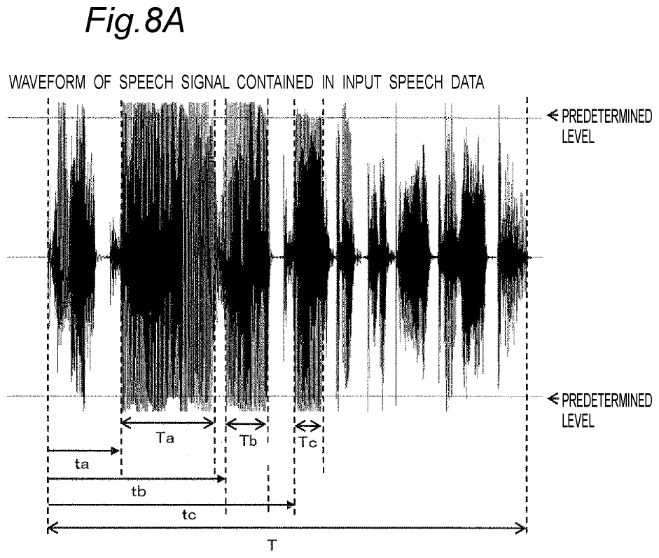

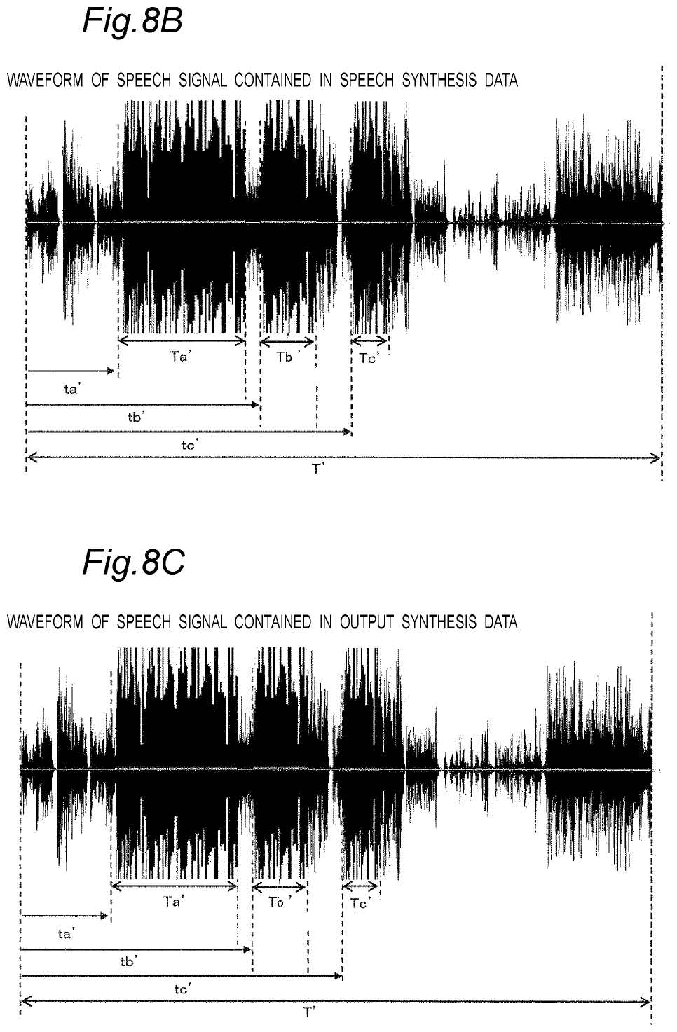

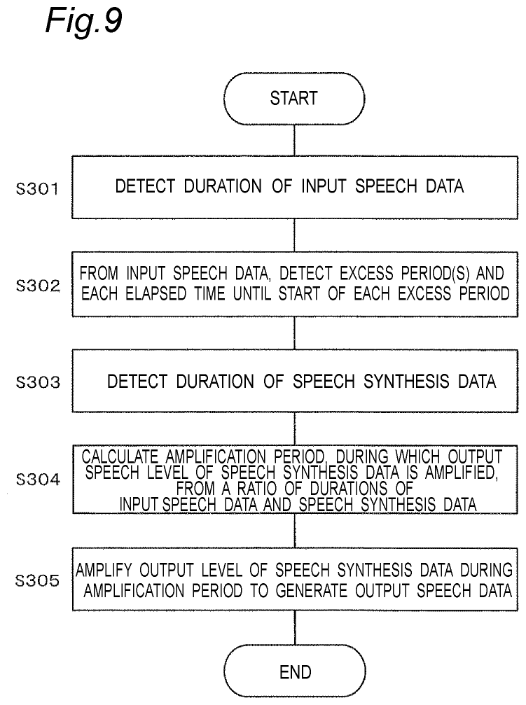

FIGS. 8A, 8B, and 8C are diagrams showing waveforms of speech signals indicated by input speech data, speech synthesis data and output speech data, respectively. FIG. 9 is a flowchart illustrating process of generating output speech data in the translation apparatus 1 of Embodiment 2.

In FIG. 9, at the beginning, the control circuit 20 of the translation apparatus 1 detects a duration of the input speech data as the level detection process 21 (S301). In the example of FIG. 8A, the control circuit 20 detects a duration T of the input speech data.

Next, the control circuit 20 detects an excess period at which an input level of the input speech data exceeds a predetermined level and detects an elapsed time to the start time of the each excess period (S302). In the example of FIG. 8A, the control circuit 20 detects excess periods Ta, Tb, and Tc and elapsed times ta, tb and tc to start times of the respective excess periods.

Then, the control circuit 20 detects a duration of the speech synthesis data (S303). In the example of FIG. 8B, the control circuit 20 detects a duration T′ of the speech synthesis data.

Next, as the output speech conversion process 24, the control circuit 20 calculates the amplification periods Ta′, Tb′, and Tc′ and the elapsed times ta′, tb′, and tc′ to respective amplification periods in the speech synthesis data based on the following equation (S304).

Ta′=Ta×T′/T

Tb′=Tb×T′/T

Tc′=Tc×T′/T

ta′=ta×T′/T

tb′=tb×T′/T

tc′=tc×T′/T

As the output speech conversion process 24, the control circuit 20 amplifies a speech output level in the amplification period of the speech synthesis data to generate the output speech data (S305). In the example in FIG. 8C, the output speech level of the speech synthesis data in FIG. 8B is amplified during the amplification period Ta′ from a start time of the speech output to a time after a lapse of time ta′. Similarly, as shown in the output speech data in FIG. 8C, the output level of the speech synthesis data in FIG. 8B is amplified during the amplification periods Tb′ and Tc′, which start at points in time, at which times tb′ and tc′ has elapsed from a start of the speech synthesis data, respectively.

By performing a control in the way as described above, the output level is amplified during an amplification period of the output speech, which corresponds to an excess period in the input speech. Thus, the speaker(s) can understand from the output speech, which part of the input speech has an excessive level with respect to the overall period of the input speech.

### Embodiment 3

The next embodiment of the present disclosure will be described below. Configurations of the speech processing apparatus 1 and the speech processing system are the same as those in Embodiment 1.

The translation apparatus 1 of Embodiment 1 amplifies a part(s) of the post-translation speech synthesis data to output from speaker 12 to help the speaker(s) to be aware that they are inputting their speech data at an excessive volume. On the other hand, the translation apparatus 1 of the present embodiment outputs a message from the speaker 12 to audibly indicate that the speech data is being input at an excessive volume during an input of the speech data by the speaker(s). This helps the speaker(s) to be aware audibly that they are inputting speech data at an excessive volume.

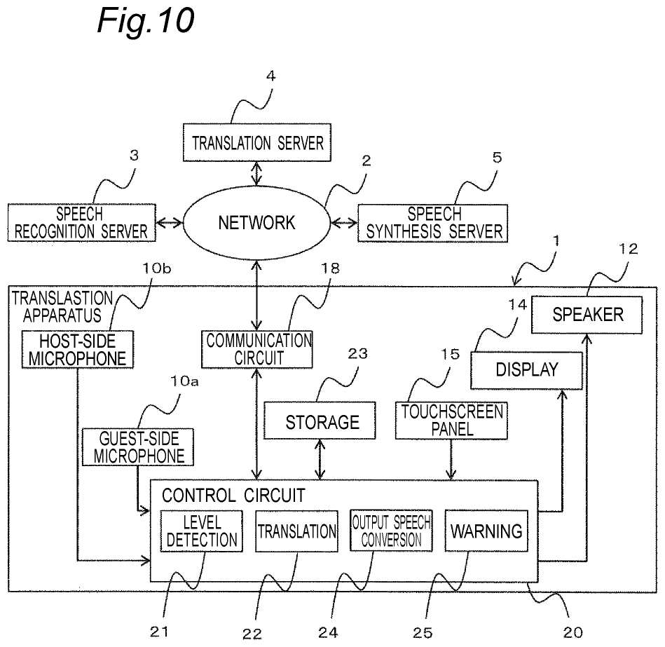

FIG. 10 is a block diagram illustrating a configuration of a translation system according to the present embodiment. In the translation apparatus 1 of FIG. 10, the control circuit 20 further performs an alert process 25 as compared to the control circuit 20 as shown in FIG. 1. By performing the alert process 25, the control circuit 25 outputs a message through the speaker 12 that the speaker(s) are inputting their speech data at an excessive volume during an input of the speech data by the speaker(s).

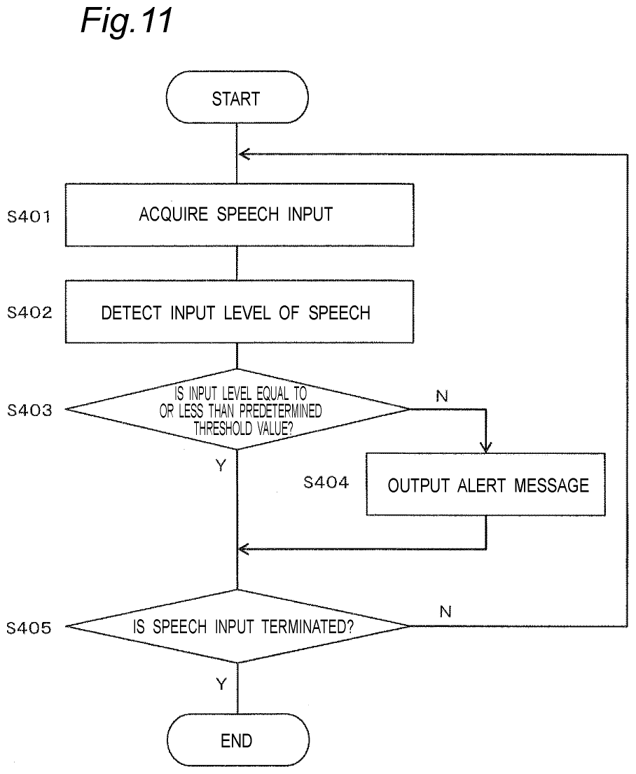

FIG. 11 is a flowchart illustrating operations of the translation apparatus 1 according to the present embodiment.

Upon detecting pressing of the speech input buttons 14a and/or 14b, the control circuit 20 of the translation apparatus 1 acquires the speech input by the speaker via the guest-side microphone 10a or the host-side microphone 10b (S401).

When the speech input button 14a is pressed or touched, the speech and/or information on the speech input from the guest-side microphone 10a is input to the translation apparatus 1. When the speech input button 14b is pressed or touched, the speech and/or information on the speech input from the host-side microphone 10b is input to the translation apparatus 1.

The control circuit 20 detects the input level of the speech acquired from the microphones 10a or 10b (S402) and compares the detected input level to a predetermined threshold value (S403). The detected input level may be an absolute value.

If the level of the input speech is greater than a predetermined threshold value (No in S403), the control circuit 20 outputs through the speaker 12 an alert message that the speech data is being input at an excessive volume (S404).

On the other hand, if the level of the input speech is equal to or less than the predetermined threshold value (Yes in S403), the control circuit 20 determines whether or not an operation to instruct an end of the speech input is made (S405). An operation to instruct the end of the speech input includes that: an operation of pressing the speech input button 14a when the speech is being acquired from the guest side microphone 10a; or an operation of pressing the speech input button 14b when the speech is being acquired from the guest side microphone 10b.

When the control circuit 20 detects that an operation to instruct the end of speech input has been made (Yes in S405), the ongoing operation is terminated. If the control circuit 20 does not detect an operation to instruct the end of speech input (No in S405), the operation returns to S401, and the control circuit 20 repeats the above operation.

As described above, the translation apparatus 1 of the present embodiment can notify the speaker(s) that they are inputting speech data at an excessive volume through a speech message, and can help them to be aware of the fact.

The control operation on the output of speech messages for alerting according to this embodiment may be applied to the translation apparatus of Embodiment 1 and/or 2.

### Embodiment 4

The next embodiment of the present disclosure will be described below. Configurations of the speech processing apparatus 1 and the speech processing system are the same as those in Embodiment 3.

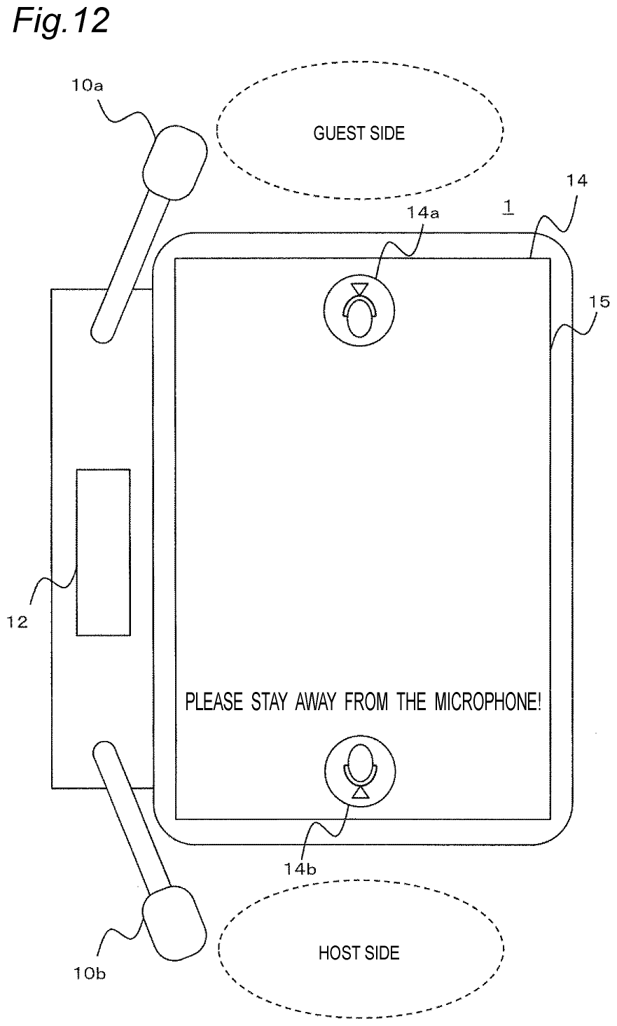

The translation apparatus 1 of Embodiment 3 helps the speaker(s) to be aware that they are inputting their speech data at an excessive volume through an output of an alert message from the speaker 12. On the other hand, as shown in FIG. 12, the translation apparatus 1 of the present embodiment displays an alert message on the display 14 to help the speaker(s) to be aware visually that they are inputting their speech data at an excessive volume.

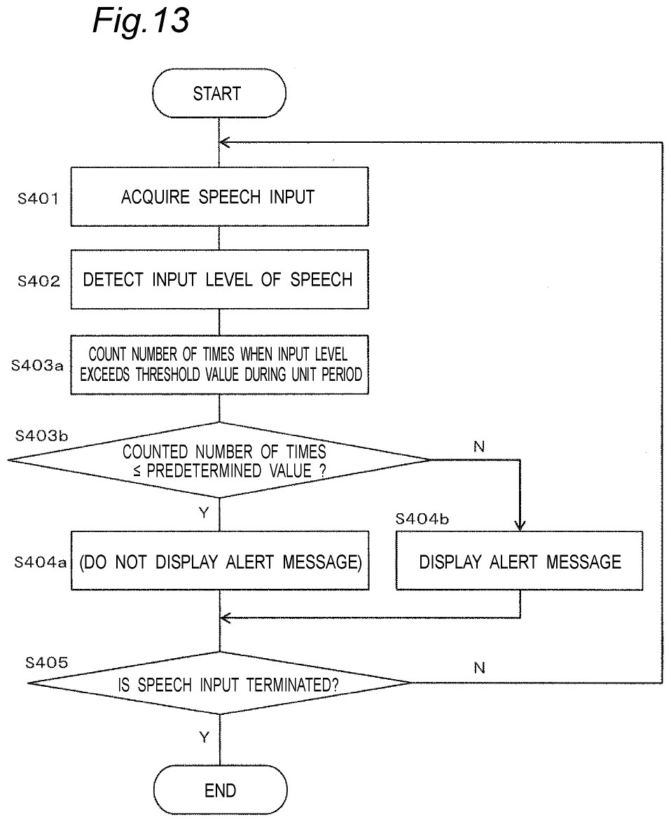

FIG. 13 is a flowchart illustrating operations of the translation apparatus 1 according to the present embodiment. In FIG. 12, the speech processing apparatus 1 as modified in this embodiment executes the processing of steps S403a, S403b, S404a, and S404b instead of the processing of steps S403 and S404.

The control circuit 20 of the translation apparatus 1 acquires the speech (S401) and detects a level of the acquired speech (S402). Then the control circuit 20 counts the number of times the input level exceeds the threshold value within the unit period (S403a). The input level may be an absolute value. If the control circuit 20 determines that the counted number is equal to or less than a predetermined value (Yes at S403a), the control circuit 20 does not display an alert message on the display 14 (S404a).

On the other hand, if the control circuit 20 determines that the counted number is greater than a predetermined value (No at S403b), the control circuit 20 displays an alert message on the display 14 (S404b). After step S404a or S404b, the control circuit 20 executes process to determine whether or not the speech input is completed (S405). As described in FIG. 13, the display 14 shows a message saying “Please Stay away from the Microphone!” as an alert message, for example.

As described above, the translation apparatus 1 of the present embodiment displays an alert message to let the speaker(s) know that they are inputting speech data at an excessive volume, and can help them to be aware of such a fact.

The control operation on the presentation of alert messages according to this embodiment may be applied to the translation apparatus of Embodiment 1 and/or 2.

### Other Embodiments

As described above, the embodiments have been described as examples of the techniques disclosed in this application. However, the techniques in the present disclosure are not limited thereto, and may be applied to the other embodiment (s) which can be obtained by making some changes, replacements, additions, and/or omissions with respect to the described embodiments. It is also possible to combine each of the components as described in the above embodiments to create one or more new embodiments.

In the above embodiment, the translation apparatus 1 is equipped with two microphones, one for the host and one for the guest. However, the translation apparatus 1 may have a single microphone that serves as a microphone for the host and also that for the guest.

The translation apparatus 1 of Embodiment 1 amplifies the output level of the speech synthesis data to a predetermined level, in which a certain portion of the speech synthesis data with a low impact on the sound quality and volume is cut out. However operations of the translation apparatus 1 are not limited to the above. For example, portions of the speech synthesis data may be removed even if such portions affect the sound quality.

In the above embodiments, the predetermined level for determining the excess period of the speech indicated by the speech synthesis data was fixed. However, the predetermined level may be changed depending on the signal level of the input speech data. For example, the greater the signal level is, the greater the predetermined level is set. As a result to be achieved by this, the excess period can be appropriately determined even when the signal level rapidly changes.

In the above embodiments, the translation apparatus 1 performs the translation process in association with external servers in a cloud computing environment, such as the speech recognition server 3, translation server 4, and speech synthesis server 5. Functions of each server are not necessarily located in the cloud environment. Rather, the translation apparatus 1 may implement at least one function among the functions provided by the speech recognition server 3, translation server 4, and speech synthesis server 5. For example, the whole process as illustrated in the flowchart of FIG. 4 may be executed by the control circuit 20 of the translation apparatus 1.

In Embodiments 1 and 2, the signal level during the amplification period of the speech signal indicated by the speech synthesis data is amplified. Instead of the amplification, the speech signal during the amplification period may be distorted.

In the above embodiments, it is demonstrated that the first language is Japanese and the second language is English.

The combination of the first and second languages is not limited to this example. Combinations of the first and second languages may include any two languages selected from a group of languages which includes Japanese, English, Chinese, Korean, Thai, Indonesian, Vietnamese, Spanish, French, Burmese, etc.

In the above embodiments, the translation apparatus is shown as an example of a speech processing apparatus. The speech processing apparatus of the present disclosure is not limited to such a translation apparatus. The technical idea discussed in the above embodiments can be applied to any electronic device that acquires a speech signal via a speech input device such as a microphone(s) and performs processing based on the input speech signals. For example, the technical idea can be applied to an interactive conversation device that is expected to be used in a store, hotel or the like.

In the above embodiment, the control circuit 20 amplifies, in the output speech conversion process 24, a level of the first output speech signal during a amplification period (the second period) with an amplification level that is greater than that of the other periods to generate the second output speech signal. The control circuit may convert the signal during the second period to a sound signal that is not based on an input speech signal, such as sounds of musical instruments, animal noises and noise from acoustic equipment. That is, with respect to the first output speech signal during the second period, the control circuit 20 may perform signal processing that is different from that to be performed to the other periods, as the output speech conversion process 24. Thus, the translation apparatus 1 can help a speaker(s) to be aware that they are inputting their speech at an excessive volume.

As described above, embodiments have been described as examples of the techniques in the present disclosure. To that end, the accompanying drawings and detailed description have been provided.

Therefore, the components illustrated in the accompanying drawings and described in the detailed description not only include components essential for solving the problem but also can include, to exemplify the techniques, components not essential for solving the problem. For this reason, it should not be immediately recognized that those unnecessary components are necessary only because those unnecessary components are described in the accompanying drawings and the detailed description.

In addition, since the above embodiments are for illustrating the techniques in the present disclosure, various modifications, replacements, additions, removals, or the like can be made without departing from the scope of the claims or the equivalent thereto.

The present disclosure can be applied to any electronic device that acquires a speech signal via a speech input device such as a microphone(s) and performs processing based on the input speech signals.

What is claimed is:

1. A speech processing apparatus comprising:
an input device that receives speech to generate an input speech signal; and
a control circuit that performs a signal generation process, a level detection process, and an output speech conversion process,
the signal generation process generating a first output speech signal based on the input speech signal,
the level detection process detecting a first period at which a signal level of the input speech signal is greater than a predetermined value, and
the output speech conversion process performing signal processing to generate a second output speech signal, the signal processing being performed to the first output speech signal during a second period that corresponds to the first period, and being different from another signal processing performed during another period; and
an output device that outputs speech based on the second output speech signal.

2. The speech processing apparatus of claim 1, wherein the control circuit generates in the output speech conversion process, the second output speech signal by amplifying a level of the first output speech signal during the second period, with an amplification level that is greater than another amplification level applied during the other period.

3. The speech processing apparatus of claim 1, wherein the control circuit generates in the output speech conversion process, the second output speech signal by converting the first output speech signal during the second period to a sound signal that is not based on the input speech signal.

4. The speech processing apparatus of claim 1, wherein
a duration of the first period in the input speech signal and a duration of the second period in the second output speech signal are equal, and
a period from a start time of the input speech signal till the first period in the input speech signal and a period from a start time of the second output speech signal till the second period in the second output speech signal are equal.

5. The speech processing apparatus of claim 1, wherein
a ratio of a duration of the first period to an overall duration of the input speech signal and a ratio of a duration of the second period to an overall duration of the second output speech signal are equal, and
a relative temporal position of the first period to an overall period of the input speech signal and a relative temporal position of the second period to an overall period of the second output speech signal are identical.

6. The speech processing apparatus of claim 1, wherein the control circuit further performs an alert process that outputs, from the output device, a speech message indicating that speech is being input at an excessive volume when the control circuit detects the first period in the level detection process.

7. The speech processing apparatus of claim 4, wherein the control circuit further performs an alert process that outputs, from the output device, a speech message indicating that speech is being input at an excessive volume when the control circuit detects the first period in the level detection process.

8. The speech processing apparatus of claim 5, wherein the control circuit further performs an alert process that outputs, from the output device, a speech message indicating that speech is being input at an excessive volume when the control circuit detects the first period in the level detection process.

9. The speech processing apparatus of claim 1, further comprising a display device, wherein
the control circuit further counts, in the level detection process, number of times when the signal level exceeds the predetermined value within the unit period of the input speech signal, and
when the control circuit determines in the level detection process that the number of times is greater than a predetermined level, the control circuit further performs an alert process that displays an alert message on the display device that the speech is to be input away from the input device.

10. The speech processing apparatus of claim 4, further comprising a display device, wherein
the control circuit further counts, in the level detection process, number of times when the signal level exceeds the predetermined value within the unit period of the input speech signal, and
when the control circuit determines in the level detection process that the number of times is greater than a predetermined level, the control circuit further performs an alert process that displays an alert message on the display device that the speech is to be input away from the input device.

11. The speech processing apparatus of claim 5, further comprising a display device, wherein
the control circuit further counts, in the level detection process, number of times when the signal level exceeds the predetermined value within the unit period of the input speech signal, and
when the control circuit determines in the level detection process that the number of times is greater than a predetermined level, the control circuit further performs an alert process that displays an alert message on the display device that the speech is to be input away from the input device.

12. The speech processing apparatus of claim 1, the control circuit changes in the level detection process, the predetermined value according to the signal level of the input speech signal.

13. A translation apparatus comprising:
an input device that receives speech with content of utterances in a first language to generate an input speech signal;
a control circuit that performs a signal generation process, a level detection process, and an output speech conversion process,
the signal generation process generating a first output speech signal which is a speech signal indicating a result of translation from the content of utterances in the input speech signal to content of utterances in a second language,
the level detection process detecting a first period at which a signal level of the input speech signal is greater than a predetermined value, and
output speech conversion process performing signal processing to generate a second output speech signal, the signal processing being performed to the first output speech signal during a second period that corresponds to the first period, and being different from another signal processing performed during another period; and
an output device that outputs speech based on the second output speech signal.

14. The translation apparatus of claim 13, wherein the control circuit generates in the output speech conversion process, the second output speech signal by amplifying a level of the first output speech signal during the second period, with an amplification level that is greater than another amplification level applied during the other period.

15. The translation apparatus of claim 13, wherein the control circuit generates in the output speech conversion process, the second output speech signal by converting the first output speech signal during the second period to a sound signal that is not based on the input speech signal.

16. The translation apparatus of claim 14, wherein
a duration of the first period in the input speech signal and a duration of the second period in the second output speech signal are equal, and
a period from a start time of the input speech signal till the first period in the input speech signal and a period from a start time of the second output speech signal till the second period in the second output speech signal are equal.

17. The translation apparatus of claim 14, wherein
a ratio of a duration of the first period to an overall duration of the input speech signal and a ratio of a duration of the second period to an overall duration of the second output speech signal are equal, and
a relative temporal position of the first period to an overall period of the input speech signal and a relative temporal position of the second period to an overall period of the second output speech signal are identical.

18. A non-transitory computer-readable storage medium storing a computer program to be executed by a control circuit of a speech processing apparatus,
the speech processing apparatus including: an input device that receives speech to generate an input speech signal; the control circuit; and an output device,
the computer program causes the control circuit to execute:
a signal generation process that generates a first output speech signal based on the input speech signal;
a level detection process that detects a first period at which a signal level of the input speech signal is greater than a predetermined value; and
an output speech conversion process that performs signal processing to generate a second output speech signal, the signal processing being performed to the first output speech signal during a second period that corresponds to the first period, and being different from another signal processing performed during another period,
wherein, based on the second output speech signal, the control circuit outputs speech through the output device.
